(19) United States
(12) Patent Application Publication
(10) Pub. No.: US 2025/0253127 A1
(43) Pub. Date: Aug. 7, 2025

(54) PLASMA PROCESSING SYSTEM WITH DIRECT CURRENT SUPERPOSITION

(71) Applicant: Tokyo Electron Limited, Tokyo (JP)

(72) Inventor: Minseok OH, Albany, NY (US)

(73) Assignee: Tokyo Electron Limited, Tokyo (JP)

(21) Appl. No.: 18/431,887

(22) Filed: Feb. 2, 2024

(51) Int. Cl. H01J 37/32; H01L 21/3065; H01L 21/67

(52) U.S. Cl. CPC H01J 37/32009; H01J 37/32899; H01L 21/3065; H01L 21/67069; H01J 2237/332

(57) ABSTRACT

A plasma processing system is disclosed. The plasma processing system includes a chamber configured to house plasma in a process space. The plasma processing system includes a first chamber component arranged along a first edge of the process space and including a silicon-based material. The plasma processing system includes a second chamber component arranged along a second edge of the process space opposite to the first edge. A first DC potential is applied to the first chamber component and a second DC potential is applied to the second chamber component, in which an absolute value of the first DC potential is larger than an absolute value of the second DC potential.

### TECHNICAL FIELD

This disclosure relates to semiconductor processing technology, and more particularly, to apparatus and methods for performing a plasma-assisted process using a chamber with silicon-based electrodes.

### BACKGROUND

In manufacturing semiconductor devices, plasma-assisted etching processes, which, for example, utilize plasma to etch a layer through a resist mask, are often used for forming a predetermined pattern on a predetermined layer disposed on a target substrate or semiconductor wafer.

### SUMMARY

At least one aspect of the present disclosure is directed to a plasma processing system. The plasma processing system includes a chamber configured to house plasma in a process space. The plasma processing system includes a first chamber component arranged along a first edge of the process space and including a silicon-based material. The plasma processing system includes a second chamber component arranged along a second edge of the process space opposite to the first edge. A first DC potential is applied to the first chamber component.

In some embodiments, the first edge and the second edge both extend horizontally.

In some embodiments, the first edge and the second edge both extend vertically.

In some embodiments, the first DC potential is provided between about −1000 volts (V) to about 0 V.

In some embodiments, a second DC potential is applied to the second chamber component. An absolute value of the first DC potential is larger than an absolute value of the second DC potential. An absolute value of a difference between the first DC potential and the second DC potential is larger than about 100 volts. An absolute value of a difference between the first DC potential and the second DC potential is larger than about 500 volts.

In some embodiments, the silicon-based material includes single crystal, polycrystalline silicon, silicon carbide, and silicon boride.

In some embodiments, the plasma is configured to form a silicon coating over the second chamber component.

At least another aspect of the present disclosure is directed to a plasma processing system. The plasma processing system includes a chamber configured to house plasma in a process space. The plasma processing system includes a first chamber component arranged along a first edge of the process space and including a silicon-based material. The plasma processing system includes a second chamber component arranged along a second edge of the process space opposite to the first edge. A first DC potential is applied to the first chamber component and a second DC potential is applied to the second chamber component, in which an absolute value of the first DC potential is larger than an absolute value of the second DC potential.

In some embodiments, the first edge and the second edge both extend horizontally. In some embodiments, the first edge and the second edge both extend vertically.

In some embodiments, the first DC potential is provided between about −1000 volts (V) to about 0 V.

In some embodiments, an absolute value of a difference between the first DC potential and the second DC potential is larger than about 100 volts.

In some embodiments, an absolute value of a difference between the first DC potential and the second DC potential is larger than about 500 volts.

In some embodiments, the silicon-based material includes single crystal, polycrystalline silicon, silicon carbide, and silicon boride.

At least yet another aspect of the present disclosure is directed to a method for operating a plasma processing system. The method includes generating plasma inside a process space of a plasma processing system. The method includes applying a first DC potential to a first chamber component arranged along a first edge of the process space, wherein the first chamber component include a silicon-based material. The method includes applying a second DC potential to a second chamber component arranged along a second edge of the process space, wherein an absolute value of the first DC potential is larger than an absolute value of the second DC potential.

In some embodiments, the silicon-based material includes single crystal, polycrystalline silicon, silicon carbide, and silicon boride.

In some embodiments, the method further includes forming a silicon-coating over the second chamber component through the plasma.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a schematic diagram of a plasma processing system, according to various embodiments.

FIG. 2 illustrates a formation mechanism of plasma inside the plasma processing system of FIG. 1, according to various embodiments.

FIG. 3 illustrates a flow chart for operating the plasma processing system of FIG. 1, according to various embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The fabrication of integrated circuits (IC) in the semiconductor industry typically employs plasma to create and assist surface chemistry within a vacuum processing system necessary to remove material from and deposit material on a substrate. In general, plasma is formed within the processing system under vacuum conditions by heating electrons to energies sufficient to sustain ionizing collisions with a supplied process gas. Moreover, the heated electrons can have energy sufficient to sustain dissociative collisions and, therefore, a specific set of gases under predetermined conditions (e.g., chamber pressure, gas flow rate, etc.) are chosen to produce a population of charged species and chemically reactive species suitable to the particular process being performed within the system (e.g., etching processes where materials are removed from the substrate or deposition processes where materials are added to the substrate).

Although the formation of a population of charged species (ions, etc.) and chemically reactive species is necessary for performing the function of the plasma processing system (i.e., material etch, material deposition, etc.) at the substrate surface, other chamber component surfaces on the interior of the plasma processing chamber are exposed to the physically and chemically active plasma and, in time, can erode. The erosion of exposed chamber components in the plasma processing system can lead to a gradual degradation of the plasma processing performance and ultimately to complete failure of the system.

As an example, during plasma etching for semiconductor device fabrication, the termination of the peripheral edge of the substrate is important and, when not addressed properly, can change plasma properties and affect etching uniformity. A chamber component is located beyond the peripheral edge of the substrate (sometimes referred to as a focus ring) and, dependent on the material composition of the focus ring, it may spread or confine plasma above the substrate to improve etching performance, such as etching uniformity, especially at the peripheral edge of the substrate. However, the focus ring is consumed during plasma etching, which in turn degrades etching uniformity. And, as a consequence, the focus ring must be replaced about every 200-400 hours the plasma processing system is in operation.

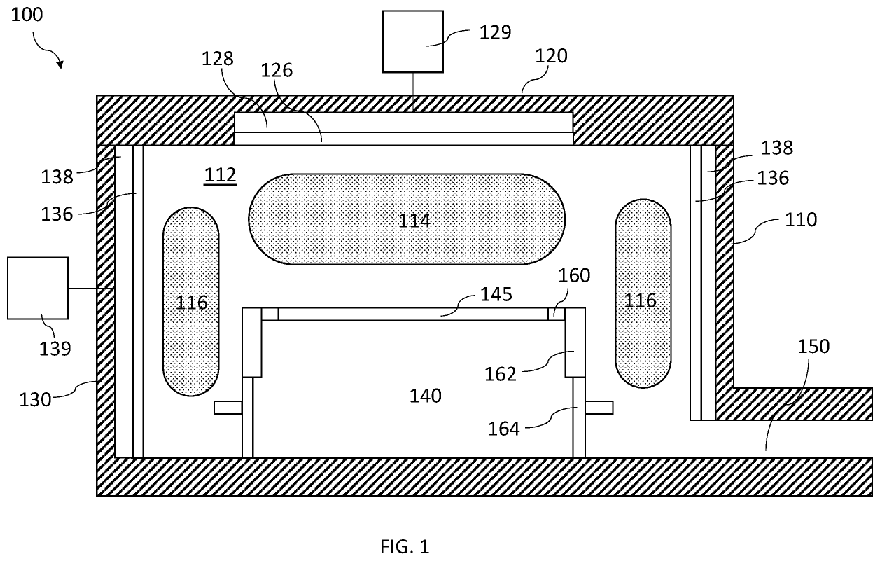

FIG. 1 illustrates a plasma processing system 100, in accordance with various embodiments of the present disclosure. The plasma processing system 100 is configured to perform a plasma-assisted process on a substrate. The plasma processing system 100 comprises a plasma processing chamber 110, an upper assembly 120, a side assembly 130, a substrate holder 140 for supporting a substrate 145, and a pumping duct 150 coupled to a vacuum pump (not shown) for providing a reduced pressure atmosphere in the plasma processing chamber 110.

The plasma processing chamber 110 can facilitate the formation of plasma in a process space 112 adjacent the substrate 145. Plasma can be utilized to create materials specific to a pre-determined materials process, and/or to aid the removal of material from the exposed surfaces of substrate 145. The plasma processing system 100 may be configured to process substrates of any size, such as 200 mm substrates, 300 mm substrates, 450 mm substrates, or larger. For example, the plasma processing system 100 may comprise a plasma etching system.

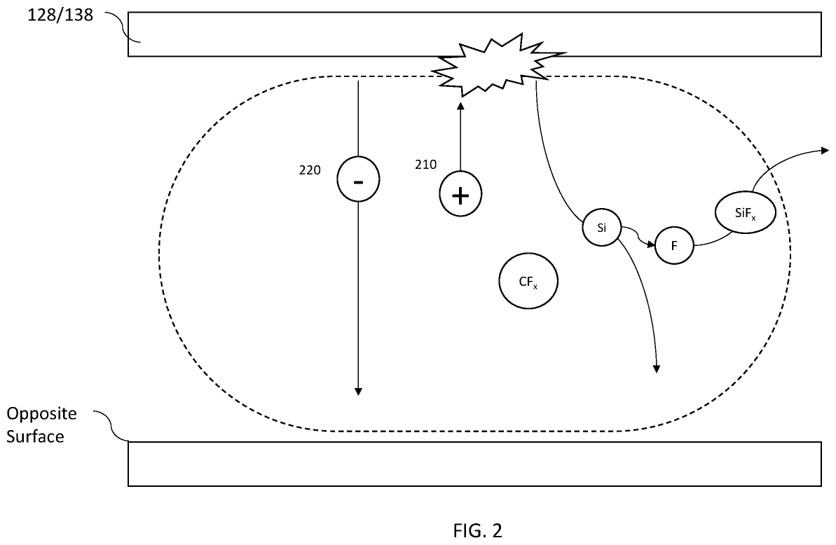

In the illustrative embodiment of FIG. 1, the upper assembly 120 may provide an upper electrode vertically opposite to the top surface of the substrate 145. The upper assembly 120 can comprise an upper electrode plate 126 and an upper electrode 128. In some embodiments, the upper electrode 128 may be electrically coupled to a (e.g., variable) DC power supply 129, as shown in FIG. 1, and the upper electrode plate 126 may be composed of a material compatible with plasma in the process space 112. The DC power supply 129 may include a bipolar DC power supply. The DC power supply 129 may further include a system configured to perform at least one of monitoring, adjusting, or controlling the polarity, current, voltage, or on/off state of the DC power supply. Once plasma (e.g., 114) is formed, the DC power supply 129 may facilitate the formation of an electron beam. An electrical filter (not shown) may be utilized to de-couple RF power from the DC power supply 129. Further, due to the erosive nature of plasma, the electrode plate 126 may include a silicon-based material, which allows silicon coating to be formed opposite to the upper electrode plate 126, according to various embodiments of the present disclosure. Examples of the silicon-based material include single crystal, polycrystalline silicon, and compounds such as silicon carbide and silicon boride. In general, the silicon-based material includes at least one electrically conductive silicon-based material, in accordance with various embodiments. Formation mechanism of such plasma will be discussed in further detail with respect to FIG. 2.

Further, the side assembly 130 may provide a side electrode laterally next to or around the substrate 145. The upper assembly 130 can comprise a side electrode plate 136 and a side electrode 138. In some embodiments, the side electrode 138 may be electrically coupled to a (e.g., variable) DC power supply 139, as shown in FIG. 1, and the side electrode plate 136 may be composed of a material compatible with plasma in the process space 112. The DC power supply 139 may include a bipolar DC power supply. The DC power supply 139 may further include a system configured to perform at least one of monitoring, adjusting, or controlling the polarity, current, voltage, or on/off state of the DC power supply. Once plasma (e.g., 116) is formed, the DC power supply 139 may facilitate the formation of an electron beam. An electrical filter (not shown) may be utilized to de-couple RF power from the DC power supply 139. Further, due to the erosive nature of plasma, the electrode plate 136 may include a silicon-based material, which allows silicon coating to be formed opposite to the side electrode plate 136, according to various embodiments of the present disclosure. Examples of the silicon-based material include single crystal and polycrystalline silicon and compounds such as silicon carbide and silicon nitride. Formation mechanism of such plasma will be discussed in further detail with respect to FIG. 2.

In some embodiments, an etching process can be performed in the plasma processing chamber 110. For example, a process gas for etching is supplied from a process gas supply source into the plasma processing chamber 110 at a predetermined flow rate through one or more gas flow channels and one or more gas delivery holes. At the same time, the interior of the plasma processing chamber 110 is exhausted by an exhaust unit to set the pressure inside the plasma processing chamber 110 to be a predetermined value within a range of, e.g., 0.1 to 150 Pa. The process gas may be selected from various gases, e.g., a gas containing a halogen element, a representative example of which is a fluorocarbon gas (CₓF_{y}), such as C₄F₈ gas. Further, the process gas may contain another gas, such as Ar gas or O₂ gas.

Application of the above-described DC potential to the upper electrode 128 creates the plasma 114 having a lower region and an upper region, in which the upper region is a sheath having higher plasma density, and more uniform radial distribution of plasma, than the lower region. Similarly, application of the DC potential to the side electrode 138 creates the plasma 116 having different (e.g., left and right) regions. The process of generating a plasma using the above-described DC potential is sometimes referred to as Direct Current Superposition (DCS), or DCS cure. For example, the DC voltage applied to upper or side electrode by the DC power supply (e.g., 129, 139) may range from approximately −1000 volts (V) to approximately 0 V, while the opposite electrode or assembly (e.g., the substrate holder 140 or shield ring 162) may be biased at ground or a higher voltage. In some embodiments, the absolute value of the voltage difference (between the opposite electrodes) has a value equal to or greater than approximately 100 V. In some other embodiments, the absolute value of the voltage difference (between the opposite electrodes) has a value equal to or greater than approximately 500 V.

In some embodiments, the substrate holder 140 further comprises a focus ring 160, a shield ring 162, and a bellows shield 164. The focus ring 160 may be interposed between the substrate 145 and the shield ring 162. The focus ring 160 may be removably fastened to the substrate holder 140. The substrate 145 can be affixed to the substrate holder 140 via a clamping system (not shown), such as a mechanical clamping system or an electrical clamping system (e.g., an electrostatic clamping system). Furthermore, the substrate holder 140 can include a heating system (not shown) or a cooling system (not shown) that is configured to adjust and/or control a temperature of the substrate holder 140 and the substrate 145. The heating system or cooling system may comprise a re-circulating flow of heat transfer fluid that receives heat from the substrate holder 140 and transfers heat to a heat exchanger system (not shown) when cooling, or transfers heat from the heat exchanger system to the substrate holder 140 when heating. Alternatively or additionally, heating/cooling elements, such as resistive heating elements, or thermo-electric heaters/coolers can be included in the substrate holder 140, as well as the chamber wall of the plasma processing chamber 110 and any other component within the plasma processing system 100.

In various embodiments, the substrate holder 140 can include a substrate holder electrode (not shown) through which a voltage (e.g., higher than the voltage applied to the upper electrode 128 as mentioned above) is coupled to the processing plasma in process space 112. For example, the substrate holder 140 can be electrically biased at ground or a negative voltage with an absolute value less than 1000 from another DC power supply (not shown) through an optional impedance match network to the substrate holder 140. Similarly, the shield ring 162 and/or the bellows shield 164 can include an inner sidewall electrode (not shown) through which a voltage (e.g., higher than the voltage applied to the side electrode 138 as mentioned above) is coupled to the processing plasma in process space 112. For example, the shield ring 162 and/or the bellows shield 164 can be electrically biased at ground or a negative voltage with an absolute value less than 1000 from yet another DC power supply (not shown) through an optional impedance match network to the substrate holder 140. In some embodiments, each of these electrodes may sometimes be referred to as a chamber component. Further, a pair of the chamber components are arranged along opposite edges of the process space 112, respectively. For example, the upper electrode 128 and the substrate holder electrode may be arranged along an upper edge and a lower edge of the process space 112, respectively. In another example, the side electrode 138 and the inner sidewall electrode may be arranged along an outer edge and an inner edge of the process space 112, respectively. In some embodiments, the upper electrode 128 and the side electrode 138 is formed as a multi-piece structure or a single-piece structure. In the example where the electrode 128/138 is formed as a multi-piece structure, different pieces can be electrically coupled to respective DC potentials.

FIG. 2 is a schematic illustration of the process of DCS resulting from application of a DC potential to an upper/side electrode of a plasma processing chamber (e.g., 110), according to various embodiments of the present disclosure. In general, application of a DC potential to the upper/side electrode creates a thicker first sheath closer to the upper/side electrode, changing the radial distribution of the plasma and increasing plasma density relative to plasmas generated without the application of a DC bias.

Specifically, the DC potential accelerates positive (e.g., Ar) ions 210 toward the upper/side electrode. The impact of positive ions on the upper/side electrode generates secondary electron emission 220 that is accelerated by the DC potential toward the opposite surface (e.g., a wafer surface, a shield ring, etc.). These generated secondary electrons, together with some electrons reflected from the top/side electrode, are of sufficient energy to penetrate through a second sheath closer to the opposite surface and affect processes at the opposite surface, including charge cancellation and cross-linking of organic films comprising a photoresist. This electron beam induced cross-linking/hardening may improve etch selectivity to organic photoresists and organic planarizers. Further, with the upper/side electrode including the silicon-based material attacked by the accelerated positive ions 210, some of the silicon atoms (e.g., generated from the upper/side electrode) can react with free fluorine radicals (e.g., supplied from the fluorocarbon gas through the plasma), producing SiFₓ, which can be easily plumbed out of the plasma processing chamber. Some of the silicon atoms may be redeposited as a silicon coating on the opposite surface.

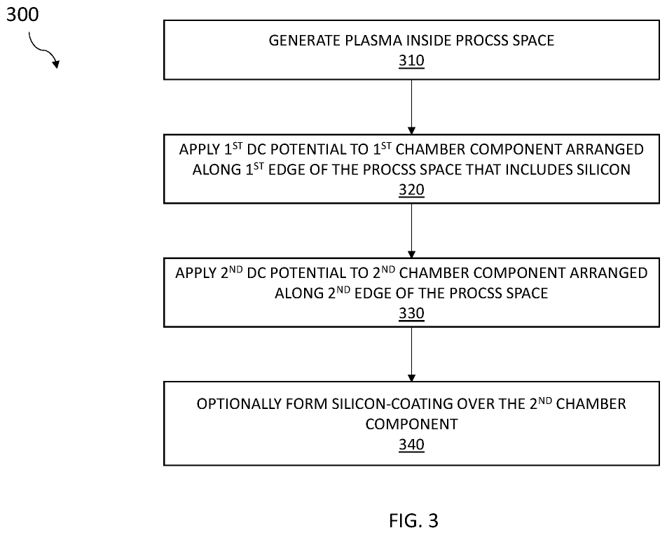

FIG. 3 illustrates a flow chart of an example method 300 for operating a plasma processing system, in accordance with various embodiments. For example, the method 300 may be performed to operate the plasma processing system 100, and thus, some of the reference numerals of FIGS. 1-2 may be reused in the following discussion of the method 300. One or more operations of the method 300 may be omitted, added, modified, or combined. The operations of the method 300 may be performed sequentially or concurrently. The operations of the method 300 can be performed in other order or sequence, not limited to those described herein.

The method 300 may start with operation 310 of generating plasma inside a process space of a plasma processing system. For example, the plasma can be generated in the process space 112. The method 300 may proceed to operation 320 of applying a first DC potential to a first chamber component arranged along a first edge of the process spacer, and to operation 330 of applying a second DC potential to a second chamber component arranged along a second edge of the process spacer. In some embodiments, the first chamber component includes a silicon-based material such as, for example, single crystal, polycrystalline silicon, silicon carbide, and silicon nitride. In one aspect, the first edge and the second edge may both extend horizontally, e.g., the upper electrode and the substrate holder electrode. In another aspect, the first edge and the second edge may both extend vertically, e.g., the side electrode and the inner electrode. Further, an absolute value of the first DC potential is larger than an absolute value of the second DC potential. For example, the first DC potential may be provided at about −1000 V and the second DC potential may be provided at about −900 V. In another example, the first DC potential may be provided at about −1000 V and the second DC potential may be provided at about 0 V. The method 300 may optionally proceed to operation 340 of forming a silicon-coating over the second chamber component through the plasma. With the first chamber component including the silicon-based material, a silicon coating can be formed over the second, opposite chamber component through the plasma.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A plasma processing system, comprising:
a chamber configured to house plasma in a process space;
a first chamber component arranged along a first edge of the process space and including a silicon-based material; and
a second chamber component arranged along a second edge of the process space opposite to the first edge, both of the first chamber component and the second chamber component including an electrically conductive material,
wherein a first DC potential is applied to the first chamber component.

2. The plasma processing system of claim 1, wherein the first edge and the second edge both extend horizontally.

3. The plasma processing system of claim 1, wherein the first edge and the second edge both extend vertically.

4. The plasma processing system of claim 1, wherein the first DC potential is provided between about −1000 volts (V) to about 0 V.

5. The plasma processing system of claim 1, wherein a second DC potential is applied to the second chamber component.

6. The plasma processing system of claim 5, wherein an absolute value of the first DC potential is larger than an absolute value of the second DC potential.

7. The plasma processing system of claim 5, wherein an absolute value of a difference between the first DC potential and the second DC potential is larger than about 100 volts.

8. The plasma processing system of claim 5, wherein an absolute value of a difference between the first DC potential and the second DC potential is larger than about 500 volts.

9. The plasma processing system of claim 1, wherein the silicon-based material includes single crystal, polycrystalline silicon, silicon carbide, and silicon boride.

10. The plasma processing system of claim 1, wherein a silicon is formed over the second chamber component.

11. A plasma processing system, comprising:
a chamber configured to house plasma in a process space;
a first chamber component arranged along a first edge of the process space and including a silicon-based material; and
a second chamber component arranged along a second edge of the process space opposite to the first edge,
wherein a first DC potential is applied to the first chamber component and a second DC potential is applied to the second chamber component, in which an absolute value of the first DC potential is larger than an absolute value of the second DC potential.

12. The plasma processing system of claim 11, wherein the first edge and the second edge both extend horizontally.

13. The plasma processing system of claim 11, wherein the first edge and the second edge both extend vertically.

14. The plasma processing system of claim 11, wherein the first DC potential is provided between about −1000 volts (V) to about 0 V.

15. The plasma processing system of claim 11, wherein an absolute value of a difference between the first DC potential and the second DC potential is larger than about 100 volts.

16. The plasma processing system of claim 11, wherein an absolute value of a difference between the first DC potential and the second DC potential is larger than about 500 volts.

17. The plasma processing system of claim 11, wherein the silicon-based material includes single crystal, polycrystalline silicon, silicon carbide, and silicon boride.

18. A method for operating a plasma processing system, comprising:
generating plasma inside a process space of a plasma processing system;
applying a first DC potential to a first chamber component arranged along a first edge of the process space, wherein the first chamber component include a silicon-based material; and
applying a second DC potential to a second chamber component arranged along a second edge of the process space, wherein an absolute value of the first DC potential is larger than an absolute value of the second DC potential.

19. The method of claim 18, wherein the first and second edge both extend vertically inside the process space.

20. The method of claim 18, further comprising forming a silicon-coating over the second chamber component through the plasma.
